(19) United States
(12) Patent Application Publication
(10) Pub. No.: US 2016/0247996 A1
(43) Pub. Date: Aug. 25, 2016

(54) LARGE FOOTPRINT, HIGH POWER DENSITY THERMOELECTRIC MODULES FOR HIGH TEMPERATURE APPLICATIONS

(71) Applicant: Novus Energy Technologies, Inc., Raleigh, NC (US)

(72) Inventors: Peter McLean Thomas, Raliegh, NC (US); Rama Venkatasubramanian, Cary, NC (US)

(73) Assignee: Novus Energy Technologies, Inc., Raleigh, NC (US)

(21) Appl. No.: 15/048,496

(22) Filed: Feb. 19, 2016

Related U.S. Application Data
(60) Provisional application No. 62/118,108, filed on Feb. 19, 2015.

(51) Int. Cl. H01L 35/32; H01L 35/34

(52) U.S. Cl. CPC H01L 35/325; H01L 35/34

(57) ABSTRACT

KiloWatt-level, large footprint, high power density thermoelectric modules are disclosed for high temperature applications. The thermoelectric modules utilize a compliant interface that reduces thermal mismatch stress and allows thermoelectric devices to be fabricated with dimensions greater than 6×6 cm.

### CROSS REFERENCE TO RELATED APPLICATION

This application claims priority from U.S. Provisional Patent Application No. 62/118,108 filed on Feb. 19, 2015 entitled KiloWatt-level, large footprint, low manufacture cost, high power density thermoelectric module for high temperature applications, which is hereby incorporated by reference.

### BACKGROUND

The present application relates generally to thermoelectric devices for generating electricity from heat. More particularly, the application relates to kilowatt-level, large footprint, high-power density thermoelectric modules for high-temperature applications.

Power generation and solid-state cooling have long been sought after as a solution for challenging energy problems and thermal management. Thermoelectric modules have been developed to address some of these issues, with the great majority of current applications being used for thermoelectric cooling. Bulk thermoelectric generators (TEG) have been used for converting waste heat to electrical energy. There are, however, several significant issues with existing bulk thermoelectric generators. First, current devices generally only operate in the 250-300° C. range. In addition, they typically have low efficiency (in the 4-5% range), are relatively costly, and have poor reliability. Finally, current design constraints limit the size of the current thermoelectric devices to about 4×4 cm and power output to about 10 W. Installing such small devices into a large 1 MW waste heat harvesting application would therefore require the integration of a very large number of devices (e.g., 100,000), which would be very costly and inefficient and, more importantly, likely to lead to several inter-module interconnect failures. This combination of factors has rendered these devices impractical and has impeded their widespread use and market success.

Current commercial thermoelectric device designs are adequate in low temperatures applications where 4-5% efficiency can be obtained. However a majority of waste heat applications require high temperature devices that operate at higher efficiencies.

### BRIEF SUMMARY OF THE DISCLOSURE

A thermoelectric module in accordance with one or more embodiments includes a plurality of P-N couples. Each P-N couple comprises a P-type element and an N-type element and a top electrically conductive subheader electrically connecting the P-type element to the N-type element at a top end thereof. A top common header extends over the top electrically conductive subheaders of the plurality of P-N couples, and forms a hot side of the thermoelectric module. The top common header comprises a thermally conductive dielectric material. A thermal interface is disposed between the top common header and each of the top electrically conductive subheaders to reduce thermal mismatch stress between the top common header and the plurality of P-N couples. A bottom common header extends below each of the plurality of P-N couples and forms a cold side of the thermoelectric module. The bottom common header comprises a thermally conductive dielectric material. An electrically conducting layer is disposed between the bottom common header and the plurality of P-N couples for electrically connecting the plurality of P-N couples in series.

A method of manufacturing a thermoelectric module for generating electricity from heat in accordance with one or more embodiments comprises the steps of (a) placing an electrically conductive layer on a bottom common header; (b) placing a plurality of P and N type elements in pairs forming P-N couples on the bottom common header such that the electrically conductive layer electrically connects adjacent P-N couples in series; (c) placing top subheaders on each P-N couple to electrically connect the P type element and the N type element of each P-N couple; (d) bonding the bottom header, the P-N couples, and the top subheaders together into an assembly; (e) applying a thermal interface material on each of the top subheaders; (f) placing a top common header on top of the thermal interface material on the top subheaders; and (g) securing the top common header to the bottom common header at spaced apart locations.

### BRIEF DESCRIPTION OF THE DRAWINGS

FIG. 1 is a schematic cross-section view illustrating an exemplary thermoelectric module in accordance with one or more embodiments.

FIG. 2 is a schematic top view of the thermoelectric module of FIG. 1.

FIG. 3 is another schematic top view of the thermoelectric module of FIG. 1.

FIG. 4 is a schematic top view of an exemplary alternate thermoelectric module with a tiled top header in accordance with one or more embodiments.

FIG. 5 is a schematic cross-section view of the thermoelectric module of FIG. 4.

FIG. 6 is a schematic cross-section view of an exemplary alternate thermoelectric module with a tiled top header in accordance with one or more embodiments.

FIG. 7 is a graph illustrating an exemplary power curve versus modular size for a thermoelectric module comprising half-Heusler thermoelectric materials in accordance with one or more embodiments.

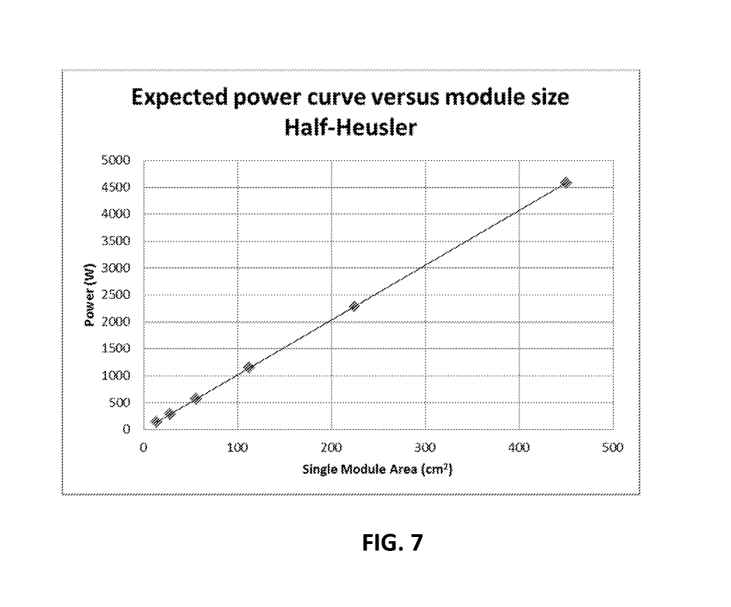

FIG. 8 is a graph illustrating a power curve versus modular size for a thermoelectric module comprising Bi2Te3 thermoelectric materials in accordance with one or more embodiments.

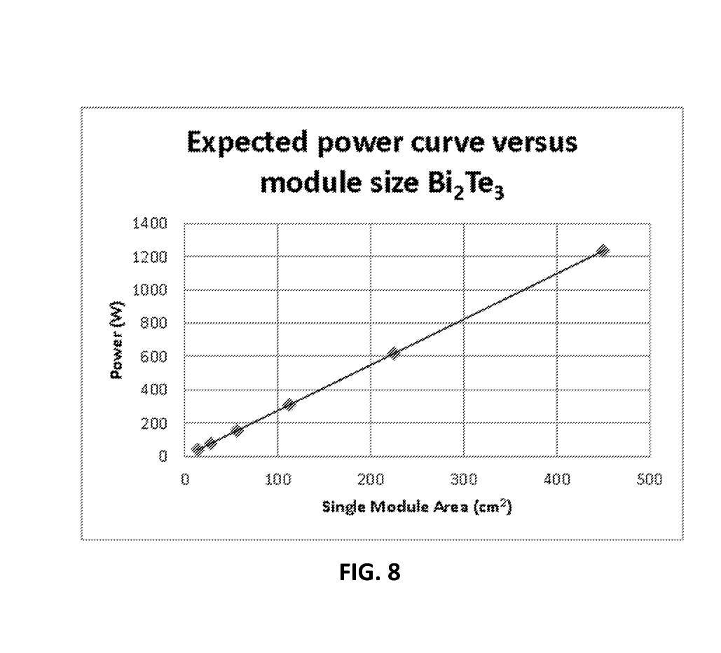

Like or identical reference numbers are used to identify common or similar elements.

### DETAILED DESCRIPTION

Various embodiments disclosed herein relate to large scale (e.g., KiloWatt-level), large footprint, high power density thermoelectric modules for high temperature applications. In accordance with one or more embodiments, thermoelectric modules utilize an interface such as a compliant interface that reduces thermal mismatch stress and allows thermoelectric devices to be fabricated with dimensions greater than 6×6 cm, the maximum size only limited to the manufacturing tooling available to build the module.

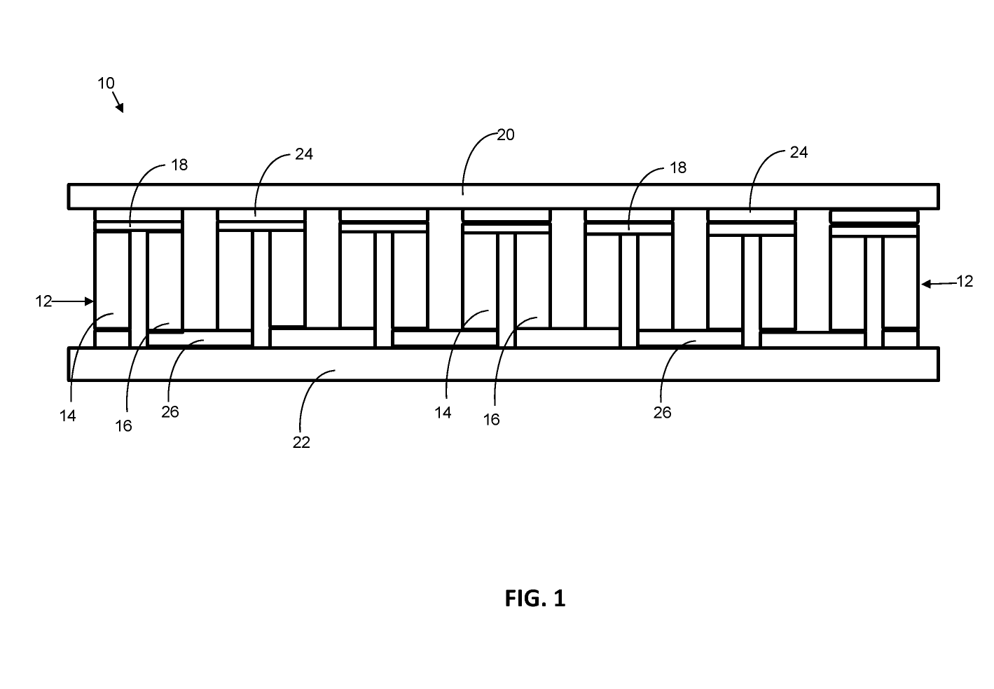

FIG. 1 schematically illustrates a thermoelectric module 10 for generating electricity from heat in accordance with one or more embodiments. The module includes a plurality of P-N couples 12, each comprising a P-type element 14 and an N-type element 16. A top subheader 18 electrically connects the P and N type elements 14, 16 in each couple 12 at a top end thereof.

The module 10 also includes a top common header 20 forming a hot side of the thermoelectric module and a bottom common header 22 forming a cold side of the thermoelectric module 10. The top common header 20 extends over the top subheaders 18 of all of the P-N couples. A compliant thermal interface 24 is disposed directly between the top common header 20 and each of the top subheaders 18 to substantially eliminate thermal mismatch stress caused by thermal coefficient of expansion differences between the top common header 20 and the top subheaders 18, which is particularly problematic in a module with a large footprint. The presence of the compliant thermal interface 24 enables the top common header 20 to expand with increasing temperature with no substantially shear stress applied on the individual P-N couples.

The bottom common header 22 extends below the plurality of P-N couples. An electrically conducting layer 26, e.g., a copper bus, is provided on the bottom common header 22 to electrically connect the P-N couples of the module in series.

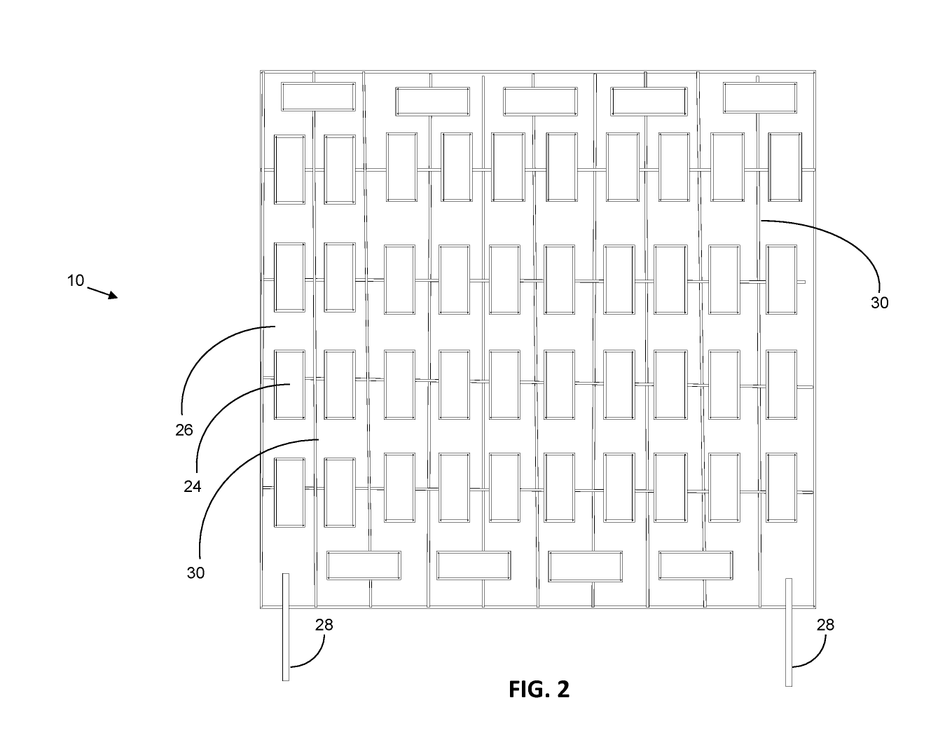

FIG. 2 schematically illustrates a top view of the large footprint thermoelectric module 10 of FIG. 1 with the top common header 20 not shown for purposes of illustration. In this view, the compliant thermal interface 24 above the P-N couples and the copper bus 26 are visible along with electric connections 28 to the copper bus 26. The copper bus 26 is segmented by isolation elements 30.

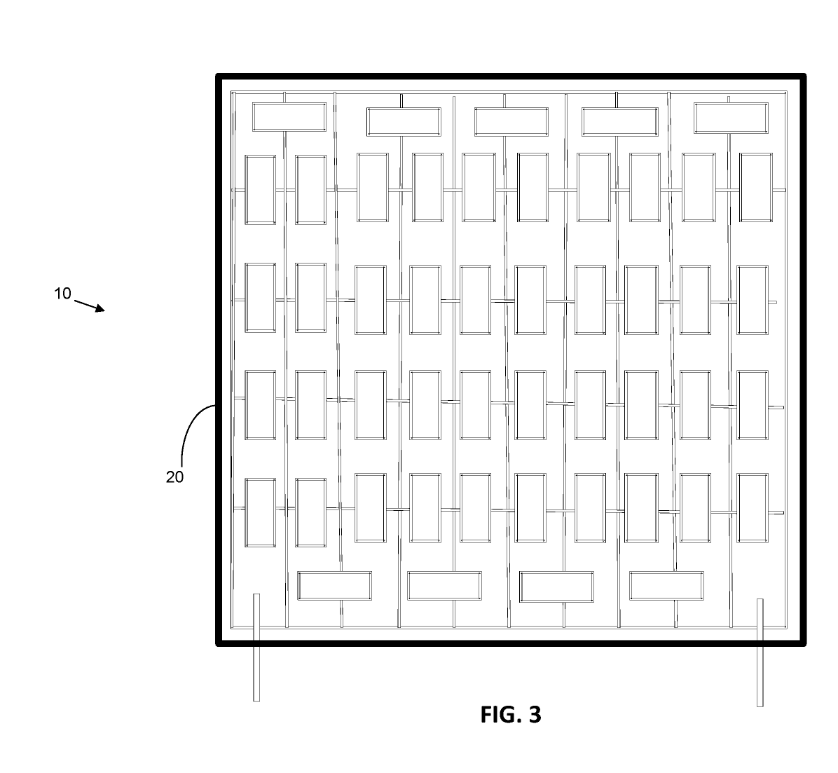

FIG. 3 shows the module 10 of FIG. 1 with the top common header 20 shown as transparent for purposes of illustration.

In accordance with one or more embodiments, the P and N type elements comprise high-temperature thermoelectric bulk materials such as, e.g., half-Heusler or similar high or low temperature thermoelectric materials. Other materials can also be used including, e.g., Bi2Te3, PbTe, TAGS, PbSe, Si, SiGe, and Skutterudite mid-temperature materials.

The P and N type elements are fabricated with contact metallizations (a bonding metal layer) on their ends to facilitate bonding to the top subheader 18 and the copper bus 26 as discussed below.

The top and bottom common headers 20, 22 comprise a thermally conductive dielectric material such as, e.g., ceramic, silicon, aluminum oxide, or aluminum nitride.

The bottom header 22 is prepared with the copper bus 26, and is bonded to the contact metallizations at the bottom of the P-N couples to affix the P-N couples to the bottom header 22. The copper bus is bonded to the bottom header or an evaporated adhesion layer is used as a base layer on which the copper bus is applied.

The individual couple top subheaders 18 comprise electrically conductive metal strips attached to the contact metallizations positioned on top of the P-N couples. The electrically conductive metal strips comprise material such as tungsten or similar high-temperature refractory metals, which is capable of withstanding high temperatures without oxidizing.

The thermally compliant material is then applied to the subheaders 18. The thermally compliant material can comprise, e.g., a liquid metal or a metal paste or a compliant thermal pad that is thermally conductive but electrically insulating.

The top common header 20 is then placed on top of the thermally compliant material 24 on the top subheaders 18.

In accordance with one or more alternate embodiments, a thermally conductive pad such as, e.g., a graphite pad, is used in place of the thermally compliant material. In this case, a dielectric material is placed between the pad and the top subheaders. Optionally, the subheaders can be fabricated to have two layers. A bottom layer comprising a conductive metal strip is bonded to a top layer comprising a dielectric material such as aluminum nitride or aluminum oxide. This way a compliant pad that is both electrically and thermally conductive (such as graphite thermal interface pad) can be used between the top common header 20 and the metal strips 18 on the P-N couples 12.

The top common header 20 is then secured to the bottom common header 22, e.g., at spaced apart locations such as at the corners of the module.

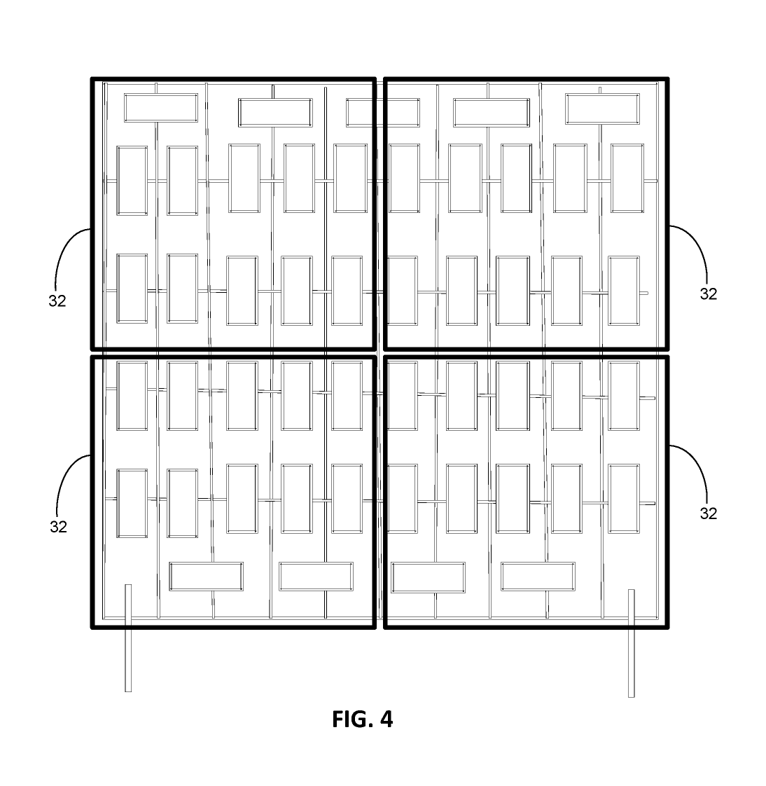

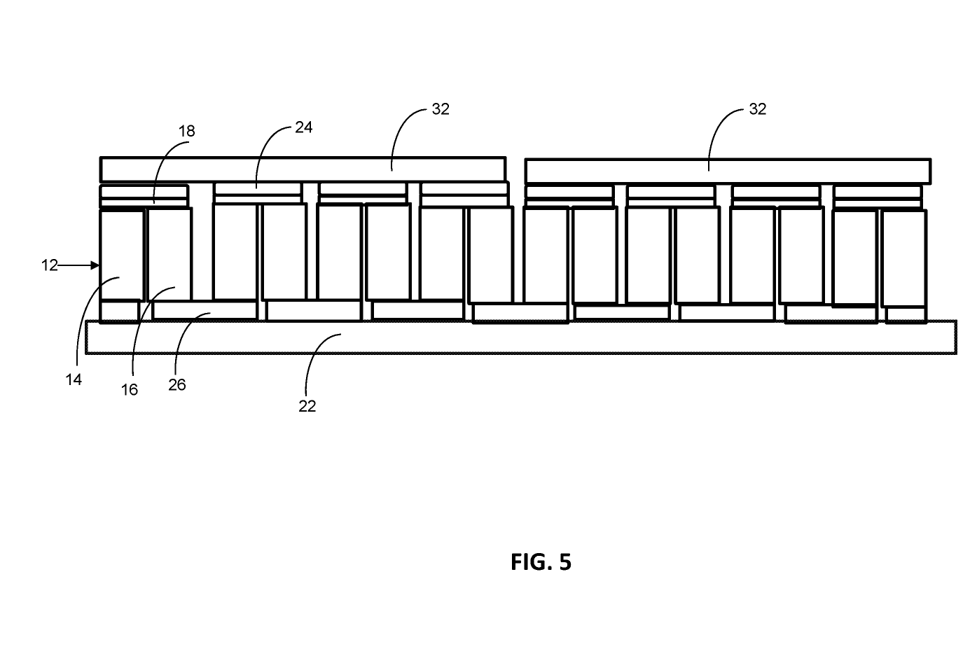

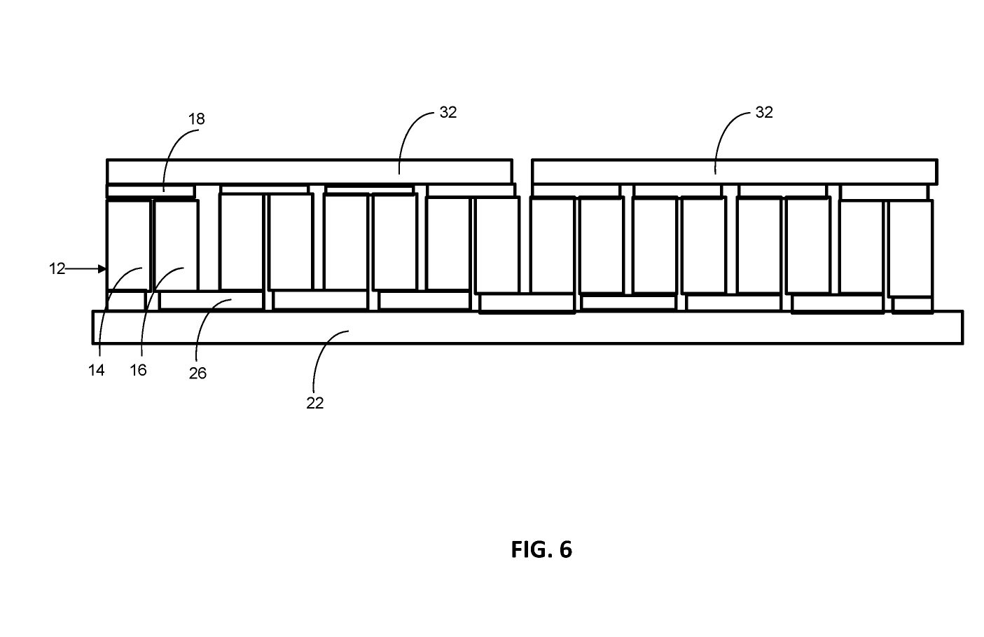

In accordance with one or more embodiments, the top common header can comprise a plurality of separate tiles 32 as shown in FIGS. 4-6 (instead of a single tile as shown in FIG. 1). (The separate tiles 32 in FIG. 4 are shown transparently for purposes of illustration.) In accordance with one or more embodiments, this tiled top header is used with the compliant interface 24 as shown in FIG. 5. In accordance with one or more alternate embodiments, the tiled top header is used without the compliant interface 24 as shown in FIG. 6.

Thermoelectric modules in accordance with one or more embodiments are particularly suitable for high temperature waste heat harvesting and power generation. Heat-to-electric power conversion at high temperatures is advantageously performed utilizing the advanced thermoelectric materials and module design of thermoelectric modules in accordance with one or more embodiments. The advanced high temperature materials allow high efficiency operation at high temperatures. The advanced module design, which significantly reduces the thermal expansion stresses at high temperatures, enables a large footprint size reducing the number of modules needed to build a scaled up power generation system. Numerous low temperature devices can be replaced by one high temperature module that can withstand the higher temperatures and be inexpensive to produce.

Thermoelectric modules in accordance with one or more embodiments can have a large footprint, high power density, and be closely packed. The thermoelectric modules can operate at high temperatures and at high efficiency. In addition, they are low in cost because integration is simplified as fewer modules are required for scaled-up power generation and waste heat harvesting applications. In one non-limiting example, a single thermoelectric module in accordance with one or more embodiments having a 15×15 cm size generates 1000 W of power at a power density of 4.4 W/cm2. The thermoelectric module can operate at high temperatures (e.g., 600-800° C.) with high efficiency (greater than 10%) and has a low $0.10/W module cost and low system costs.

Known thermoelectric device dimensions are typically limited to about a 6×6 cm size primarily because of high thermal stress exerted by the top header, which is hard bonded to the individual thermoelectric elements. The top header expands and thereby exerts shear stress on the outer thermoelectric elements in the module as the top header is heated to higher temperatures, causing cracking and fracturing of the thermoelectric elements with repeated temperature cycling of the thermoelectric device. The bigger the top header, the larger the shear stress is on the outermost thermoelectric elements. Because of this, the commercially available thermoelectric devices are typically limited in size to about 6×6 cm.

Thermoelectric devices in accordance with one or more embodiments utilize a compliant interface that allows devices to be fabricated with dimensions greater than 6×6 cm, the maximum size limited only to the manufacturing tooling available to build the module.

The high-temperature thermoelectric materials used in the thermoelectric modules in accordance with one or more embodiments comprise half-Heusler or similar high-temperature thermoelectric materials with ZT greater than 1. The high ZT, which can be achieved by nanostructuring and doping optimization, enables efficiencies greater than 10% to be achieved. Efficiencies of 12-15% are achievable with high temperature materials with ZTs greater than 1.5. The low cost, large footprint, closely packed thermoelectric module design also works with mid- and low-temperature thermoelectric materials.

The large footprint module in accordance with one or more embodiments takes advantage of the advanced module design that has minimal thermal mismatch stress between top common header and individual P-N couples. The compliant thermal interface between the thermoelectric couples top subheader and top common header substantially eliminates thermal mismatch stress that would occur in a module with a large footprint. As the top header of the module is heated and expands, the compliant thermal interface relieves the shear stress so that substantially no shear stress is exerted from the top header expansion to the individual couples of the module. Because shear stress from the top header expansion is effectively eliminated, the module has significantly improved reliability from thermal cycling over conventional hard bonded top header module designs. The low stress design is a breakthrough approach to fabricating large footprint, low cost, reliable modules for integration into large waste heat harvesting systems.

The close packed module design in accordance with one or more embodiments takes advantage of advanced semiconductor processing tools to achieve very high power density. For example, an automated pick and place tool can be used having the resolution to place thermoelectric elements with a resolution sufficient to fabricate the close packed design with >80% packing fraction.

The following illustrates an exemplary method of manufacturing a thermoelectric device in accordance with one or more embodiments.

P and N type elements are placed on the bottom header. The P and N type elements are fabricated with contact metallizations.

The bottom header is prepared with the electrically conducting layer.

The individual couple top subheaders 18 are placed on top of each P-N pair of elements to form numerous P-N couples.

The whole assembly is then reflown in a furnace to bond the bottom header, the P-N elements, and top subheader together into one assembly.

The compliant thermal interface material is then applied to the top subheaders.

The top common header is then placed on top and affixed into place using a high temperature adhesive that bonds only the two opposite corners or sides (or other spaced apart locations) of the top common header to the bottom header of the device. This allows the header to grow in size without putting undue shear stress on the individual couples.

Thermoelectric modules in accordance with various embodiments have a large footprint, low cost, high power output, high power density, and high temperature design. However the power density of the module can be varied based on the specific application requirements by varying the packing fraction through changes in the element cross sectional area. Also the footprint of module can be varied from 6×6 cm to a size as large as the manufacturing tooling will permit.

A thermoelectric module in accordance with one or more embodiments can be used as follows. The hot side of the module is heated, e.g., to 750° C. (or up to the specified hot side temperature) and cooled on the cold side, e.g., to 50° C. (or the specified cold side temperature). A high power output is possible based on the large footprint and high power density of the module using power conditioning electronics, which include an electronic load matching circuit. Modules in accordance with one or more embodiments can be used in mid-to-large scale high temperature power generation or waste heat harvesting applications where low module fabrication and integration costs, high power density, and efficiency are important in the overall system design.

Thermoelectric modules in accordance with various embodiments have numerous applications including, but not limited to, waste heat harvesting in power plants (e.g., nuclear, fossil fuel, and geothermal), industrial operations, vehicles, computer server centers, and solar thermal applications.

Having thus described several illustrative embodiments, it is to be appreciated that various alterations, modifications, and improvements will readily occur to those skilled in the art. Such alterations, modifications, and improvements are intended to form a part of this disclosure, and are intended to be within the spirit and scope of this disclosure. While some examples presented herein involve specific combinations of functions or structural elements, it should be understood that those functions and elements may be combined in other ways according to the present disclosure to accomplish the same or different objectives. In particular, acts, elements, and features discussed in connection with one embodiment are not intended to be excluded from similar or other roles in other embodiments. Additionally, elements and components described herein may be further divided into additional components or joined together to form fewer components for performing the same functions.

Accordingly, the foregoing description and attached drawings are by way of example only, and are not intended to be limiting.

1. A thermoelectric module for generating electricity from heat, comprising:
a plurality of P-N couples, each P-N couple comprising a P-type element and an N-type element and a top electrically conductive subheader electrically connecting the P-type element to the N-type element at a top end thereof;
a top common header extending over the top electrically conductive subheaders of the plurality of P-N couples, and forming a hot side of the thermoelectric module, the top common header comprising a thermally conductive dielectric material;
a thermal interface between the top common header and each of the top electrically conductive subheaders to reduce thermal mismatch stress between the top common header and the plurality of P-N couples;
a bottom common header extending below each of the plurality of P-N couples and forming a cold side of the thermoelectric module, the bottom common header comprising a thermally conductive dielectric material; and
an electrically conducting layer between the bottom common header and the plurality of P-N couples for electrically connecting the plurality of P-N couples in series.

2. The module of claim 1, wherein the module has a footprint of greater than 6 cm×6 cm for large scale applications.

3. The module of claim 1, wherein the module has a footprint of at least 15 cm×15 cm for large scale applications.

4. The module of claim 1, wherein the P-type elements and the N-type elements of the P-N couples comprise high-temperature thermoelectric bulk materials.

5. The module of claim 1, wherein the P-type elements and the N-type elements of the P-N couples comprise half-Heusler high temperature materials, Bi2Te3, PbTe, TAGS, PbSe, Si, SiGe, or Skutterudite low or mid-temperature materials.

6. The module of claim 1, wherein the interface is a compliant interface comprising liquid metal or metal paste.

7. The module of claim 1, wherein the interface comprises a thermally conductive pad, and wherein each of the subheaders comprises a bottom layer comprising a conductive metal strip bonded to a top layer comprising a dielectric material, said top layer being in contact with the thermally conductive pad.

8. The module of claim 7, wherein in the thermally conductive pad comprises a graphite pad.

9. The module of claim 1, wherein the top electrically conductive subheaders comprise tungsten.

10. The module of claim 1, wherein the top common header and the bottom common header are attached to each other at spaced apart locations on the module.

11. The module of claim 10, wherein the top common header and the bottom common header are attached using a high temperature, low CTE (coefficient of thermal expansion), compliant adhesive at at least two locations at corners or sides of the module.

12. The module of claim 1, wherein the top common header comprises a plurality of separate tiles.

13. A method of manufacturing a thermoelectric module for generating electricity from heat, comprising the steps of:
(a) placing an electrically conductive layer on a bottom common header;
(b) placing a plurality of P and N type elements in pairs forming P-N couples on the bottom common header such that the electrically conductive layer electrically connects adjacent P-N couples in series;
(c) placing top subheaders on each P-N couple to electrically connect the P type element and the N type element of each P-N couple;
(d) bonding the bottom header, the P-N couples, and the top subheaders together into an assembly;
(e) applying a thermal interface material on each of the top subheaders;
(f) placing a top common header on top of the thermal interface material on the top subheaders; and
(g) securing the top common header to the bottom common header at spaced apart locations.

14. The method of claim 13, wherein step (g) comprises using a high temperature low CTE (coefficient of thermal expansion), compliant adhesive to bond the top common header to the bottom common header at two or more locations at corners or sides of the module.

15. The method of claim 13, wherein step (d) comprises bonding the bottom header, the P-N couples, and the top subheaders together in a reflow furnace.

16. The method of claim 13, wherein the P-type elements and the N-type elements of the P-N couples comprise high-temperature thermoelectric bulk materials.

17. The method of claim 13, wherein the P-type elements and the N-type elements of the P-N couples comprise half-Heusler high temperature materials, Bi2Te3, PbTe, TAGS, PbSe, Si, SiGe, or Skutterudite mid or low temperature materials.

18. The method of claim 13, wherein the thermal interface is a compliant interface comprising liquid metal or metal paste.

19. The method of claim 13, wherein the thermal interface comprises a thermally conductive pad, and the method further comprises placing dielectric material between the thermally conductive pad and each of the top subheaders.

20. The method of claim 19, wherein in the thermally conductive pad comprises a graphite pad.

21. The method of claim 13, wherein the top subheaders comprise tungsten.
